(19) United States
(12) Patent Application Publication
(10) Pub. No.: US 2025/0062294 A1
(43) Pub. Date: Feb. 20, 2025

(54) STAGGERED STACKED LIGHT-EMITTING CHIP STRUCTURE, METHOD OF MANUFACTURING THE SAME, AND IMAGE DISPLAY DEVICE USING THE SAME

(71) Applicant: ASTI GLOBAL INC., TAIWAN, Taichung City (TW)

(72) Inventor: CHIEN-SHOU LIAO, Taichung City (TW)

(21) Appl. No.: 18/780,530

(22) Filed: Jul. 23, 2024

Related U.S. Application Data
(60) Provisional application No. 63/532,885, filed on Aug. 15, 2023.

(51) Int. Cl. H01L 25/075

(52) U.S. Cl. CPC H01L 25/0756

(57) ABSTRACT

A staggered stacked light-emitting chip structure and a method of manufacturing the same, and an image display device are provided. The staggered stacked light-emitting chip structure includes a first light-emitting chip, a second light-emitting chip and a third light-emitting chip. The first, second and third light-emitting chips are stacked sequentially from bottom to top and horizontally staggered from each other. The vertical projection of the second positive electrode pad and the vertical projection of the second negative electrode pad of the second light-emitting chip do not fall on the first top light-emitting surface of the first light-emitting chip. The vertical projection of the third positive electrode pad and the vertical projection of the third negative electrode pad of the third light-emitting chip do not fall on the first top light-emitting surface of the first light-emitting chip and the second top light-emitting surface of the second light-emitting chip.

### CROSS-REFERENCE TO RELATED PATENT APPLICATION

This application claims the benefit of priority to the U.S. Provisional Patent Application Ser. No. 63/532,885, filed on Aug. 15, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a stacked light-emitting chip structure and a method of manufacturing the same, and more particularly to a staggered stacked light-emitting chip structure, a method of manufacturing the staggered stacked light-emitting chip structure, and an image display device using the staggered stacked light-emitting chip structure.

### BACKGROUND OF THE DISCLOSURE

In the related art, an LED display device can provide a pixel image through the cooperation of a red LED chip, a green LED chip and a blue LED chip. However, the red LED chip, the green LED chip and the blue LED chip that can cooperate with each other to generate the pixel image need to be placed side by side on a circuit substrate, which will occupy a larger space.

### SUMMARY OF THE DISCLOSURE

In response to the above-referenced technical inadequacy, the present disclosure provides a staggered stacked light-emitting chip structure and a method of manufacturing the same, and an image display device using the staggered stacked light-emitting chip structure.

In order to solve the above-mentioned problems, one of the technical aspects adopted by the present disclosure is to provide a staggered stacked light-emitting chip structure, which includes a first light-emitting chip, a second light-emitting chip and a third light-emitting chip. The first light-emitting chip has a first top light-emitting surface, a first bottom non-soldering pad area, a first positive electrode pad and a first negative electrode pad. The second light-emitting chip has a second top light-emitting surface, a second bottom non-soldering pad area, a second positive electrode pad and a second negative electrode pad. The third light-emitting chip has a third top light-emitting surface, a third bottom non-soldering pad area, a third positive electrode pad and a third negative electrode pad. The first light-emitting chip, the second light-emitting chip and the third light-emitting chip are stacked sequentially from bottom to top, and the first light-emitting chip, the second light-emitting chip and the third light-emitting chip are horizontally staggered from each other. A vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip. A vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

In order to solve the above-mentioned problems, another one of the technical aspects adopted by the present disclosure is to provide a method for manufacturing a staggered stacked light-emitting chip structure, which includes: providing a circuit substrate; placing a first light-emitting chip on the circuit substrate to electrically connect to the circuit substrate, in which the first light-emitting chip has a first top light-emitting surface, a first bottom non-soldering pad area, a first positive electrode pad and a first negative electrode pad; stacking a second light-emitting chip on the first light-emitting chip to electrically connect to the circuit substrate, in which the second light-emitting chip has a second top light-emitting surface, a second bottom non-soldering pad area, a second positive electrode pad and a second negative electrode pad; and stacking a third light-emitting chip on the second light-emitting chip to electrically connect to the circuit substrate, in which the third light-emitting chip has a third top light-emitting surface, a third bottom non-soldering pad area, a third positive electrode pad and a third negative electrode pad. The first light-emitting chip, the second light-emitting chip and the third light-emitting chip are stacked sequentially from bottom to top, and the first light-emitting chip, the second light-emitting chip and the third light-emitting chip are horizontally staggered from each other. A vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip. A vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

In order to solve the above-mentioned problems, yet another one of the technical aspects adopted by the present disclosure is to provide an image display device, which includes a circuit substrate and a plurality of staggered stacked light-emitting chip structures disposed on the circuit substrate and electrically connected to the circuit substrate. Each of the staggered stacked light-emitting chip structures includes a first light-emitting chip, a second light-emitting chip and a third light-emitting chip. The first light-emitting chip has a first top light-emitting surface, a first bottom non-soldering pad area, a first positive electrode pad and a first negative electrode pad, the second light-emitting chip has a second top light-emitting surface, a second bottom non-soldering pad area, a second positive electrode pad and a second negative electrode pad, and the third light-emitting chip has a third top light-emitting surface, a third bottom non-soldering pad area, a third positive electrode pad and a third negative electrode pad. The first light-emitting chip, the second light-emitting chip and the third light-emitting chip are stacked sequentially from bottom to top, and the first light-emitting chip, the second light-emitting chip and the third light-emitting chip are horizontally staggered from each other. A vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip. A vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

Therefore, in the staggered stacked light-emitting chip structure provided by the present disclosure, by virtue of “the first light-emitting chip, the second light-emitting chip and the third light-emitting chip being stacked sequentially from bottom to top,” “the first light-emitting chip, the second light-emitting chip and the third light-emitting chip being horizontally staggered from each other,” “the vertical projection of the second positive electrode pad and the vertical projection of the second negative electrode pad of the second light-emitting chip that do not fall on the first top light-emitting surface of the first light-emitting chip” and “the vertical projection of the third positive electrode pad and the vertical projection of the third negative electrode pad of the third light-emitting chip that do not fall on the first top light-emitting surface of the first light-emitting chip and the second top light-emitting surface of the second light-emitting chip,” when the first light-emitting chip, the second light-emitting chip and the third light-emitting chip are stacked in sequence, the mutual optical influence between the projection beam generated by the first light-emitting chip, the projection beam generated by the second light-emitting chip and the projection beam generated by the third light-emitting chip can be minimized (or the mutual blocking influence between the first light-emitting chip, the second light-emitting chip and the third light-emitting chip can be minimized).

Furthermore, in the method for manufacturing the staggered stacked light-emitting chip structure provided by the present disclosure, by virtue of “providing a circuit substrate, placing a first light-emitting chip on the circuit substrate to electrically connect to the circuit substrate, stacking a second light-emitting chip on the first light-emitting chip to electrically connect to the circuit substrate, and stacking a third light-emitting chip on the second light-emitting chip to electrically connect to the circuit substrate,” “the first light-emitting chip, the second light-emitting chip and the third light-emitting chip being stacked sequentially from bottom to top,” “the first light-emitting chip, the second light-emitting chip and the third light-emitting chip being horizontally staggered from each other,” “the vertical projection of the second positive electrode pad and the vertical projection of the second negative electrode pad of the second light-emitting chip that do not fall on the first top light-emitting surface of the first light-emitting chip” and “the vertical projection of the third positive electrode pad and the vertical projection of the third negative electrode pad of the third light-emitting chip that do not fall on the first top light-emitting surface of the first light-emitting chip and the second top light-emitting surface of the second light-emitting chip,” when the first light-emitting chip, the second light-emitting chip and the third light-emitting chip are stacked in sequence, the mutual optical influence between the projection beam generated by the first light-emitting chip, the projection beam generated by the second light-emitting chip and the projection beam generated by the third light-emitting chip can be minimized (or the mutual blocking influence between the first light-emitting chip, the second light-emitting chip and the third light-emitting chip can be minimized).

Moreover, in the image display device provided by the present disclosure, by virtue of “the staggered stacked light-emitting chip structures being disposed on the circuit substrate and electrically connected to the circuit substrate,” “each of the staggered stacked light-emitting chip structures including a first light-emitting chip, a second light-emitting chip and a third light-emitting chip,” “the first light-emitting chip, the second light-emitting chip and the third light-emitting chip being stacked sequentially from bottom to top,” “the first light-emitting chip, the second light-emitting chip and the third light-emitting chip being horizontally staggered from each other,” “the vertical projection of the second positive electrode pad and the vertical projection of the second negative electrode pad of the second light-emitting chip that do not fall on the first top light-emitting surface of the first light-emitting chip” and “the vertical projection of the third positive electrode pad and the vertical projection of the third negative electrode pad of the third light-emitting chip that do not fall on the first top light-emitting surface of the first light-emitting chip and the second top light-emitting surface of the second light-emitting chip,” when the first light-emitting chip, the second light-emitting chip and the third light-emitting chip are stacked in sequence, the mutual optical influence between the projection beam generated by the first light-emitting chip, the projection beam generated by the second light-emitting chip and the projection beam generated by the third light-emitting chip can be minimized (or the mutual blocking influence between the first light-emitting chip, the second light-emitting chip and the third light-emitting chip can be minimized).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a staggered stacked light-emitting chip structure according to a first embodiment of the present disclosure;

FIG. 2 is a schematic side view of a first light-emitting chip of the staggered stacked light-emitting chip structure provided by the first embodiment of the present disclosure;

FIG. 3 is a schematic top view of the first light-emitting chip of the staggered stacked light-emitting chip structure provided by the first embodiment of the present disclosure;

FIG. 4 is a schematic side view of a second light-emitting chip of the staggered stacked light-emitting chip structure provided by the first embodiment of the present disclosure;

FIG. 5 is a schematic top view of the second light-emitting chip staggered and stacked on the first light-emitting chip according to the first embodiment of the present disclosure;

FIG. 6 is a schematic side view of a third light-emitting chip of the staggered stacked light-emitting chip structure provided by the first embodiment of the present disclosure;

FIG. 7 is a schematic top view of the third light-emitting chip staggered and stacked on the second light-emitting chip according to the first embodiment of the present disclosure;

FIG. 8 is a schematic perspective view of the first light-emitting chip, the second light-emitting chip and the third light-emitting chip of the staggered stacked light-emitting chip structure staggered and stacked sequentially from bottom to top according to the first embodiment of the present disclosure;

FIG. 9 is a schematic perspective view of the first light-emitting chip, the second light-emitting chip and the third light-emitting chip of the staggered stacked light-emitting chip structure staggered and stacked sequentially from bottom to top according to a second embodiment of the present disclosure; and

FIG. 10 is a schematic top view of an image display device using a plurality of staggered stacked light-emitting chip structures according to a third embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

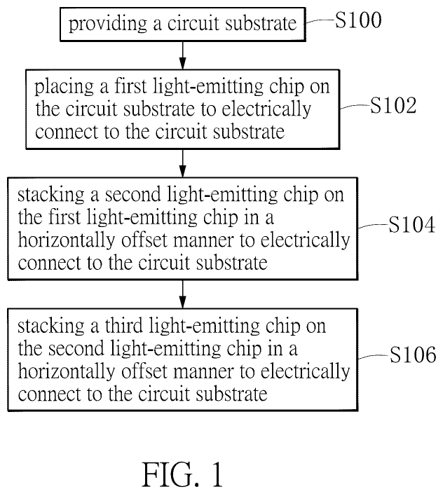

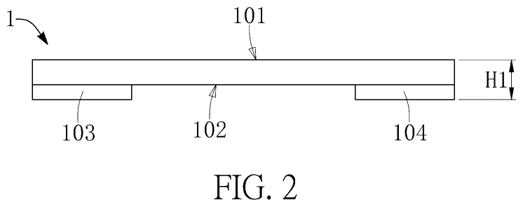

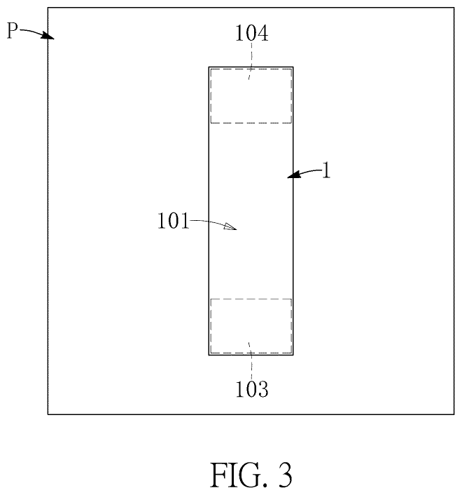

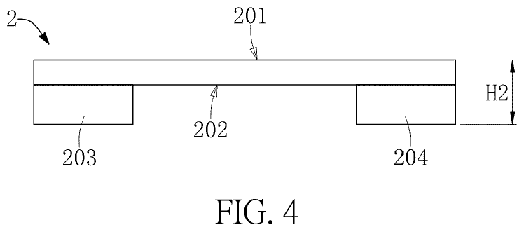

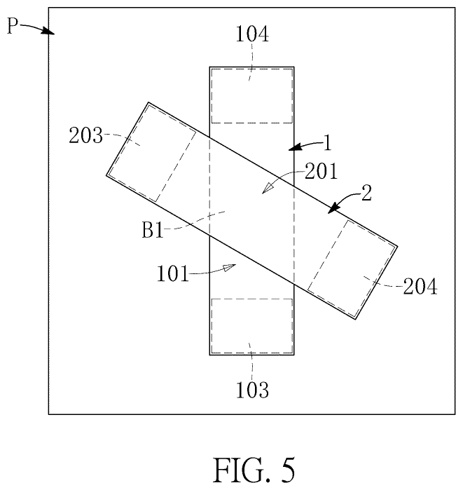

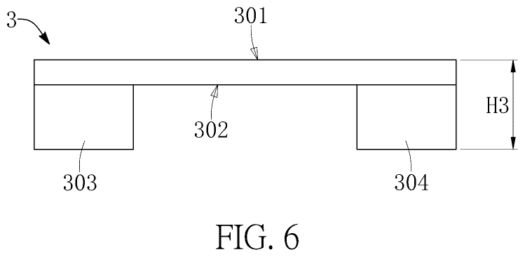

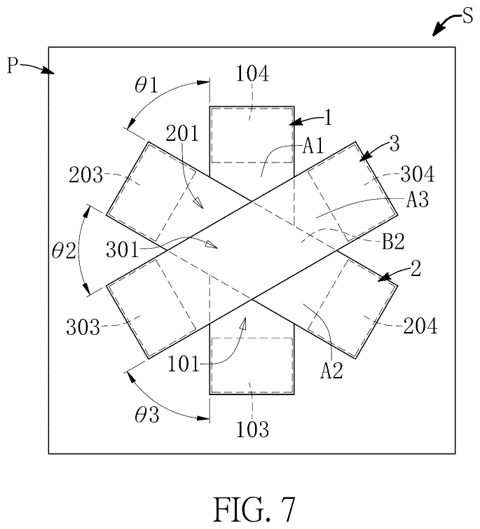

Referring to FIG. 1 to FIG. 8, a first embodiment of the present disclosure provides a method for manufacturing a staggered stacked light-emitting chip structure S, which includes the following steps: firstly, referring to FIG. 1, FIG. 2 and FIG. 3, providing a circuit substrate P (step S100), and placing a first light-emitting chip 1 on the circuit substrate P to electrically connect to the circuit substrate P through conductive materials (such as solder balls or solder paste) (step S102), in which the first light-emitting chip 1 has a first top light-emitting surface 101 (or a first top light output surface), a first bottom non-soldering pad area 102 (or a first bottom non-electrode area), a first positive electrode pad 103 and a first negative electrode pad 104; next, referring to FIG. 1, FIG. 4 and FIG. 5, stacking a second light-emitting chip 2 on the first light-emitting chip 1 in a horizontally offset manner (or a horizontally staggered manner) to electrically connect to the circuit substrate P through conductive materials (such as solder balls or solder paste) (step S104), in which the second light-emitting chip 2 has a second top light-emitting surface 201 (or a second top light output surface), a second bottom non-soldering pad area 202 (or a second bottom non-electrode area), a second positive electrode pad 203 and a second negative electrode pad 204; then, referring to FIG. 1, FIG. 6 and FIG. 7, stacking a third light-emitting chip 3 on the second light-emitting chip 2 in a horizontally offset manner (or a horizontally staggered manner) to electrically connect to the circuit substrate P through conductive materials (such as solder balls or solder paste) (step S106), in which the third light-emitting chip 3 has a third top light-emitting surface 301 (or a third top light output surface), a third bottom non-soldering pad area 302 (or a third bottom non-electrode area), a third positive electrode pad 303 and a third negative electrode pad 304.

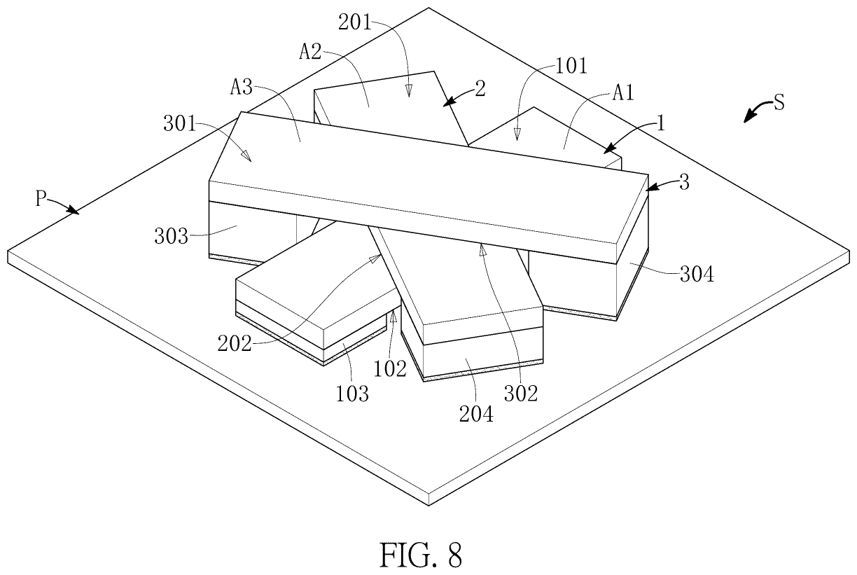

It should be noted that referring to FIG. 7 and FIG. 8, the first light-emitting chip 1, the second light-emitting chip 2 and the third light-emitting chip 3 can be stacked sequentially from bottom to top, and the first light-emitting chip 1, the second light-emitting chip 2 and the third light-emitting chip 3 can be staggered from each other (or offset from each other) in the horizontal direction. Therefore, when the first light-emitting chip 1, the second light-emitting chip 2 and the third light-emitting chip 3 are stacked and disposed sequentially from bottom to top, a vertical projection (or an orthographic projection) of the second bottom non-soldering pad area 202 of the second light-emitting chip 2 can partially fall on the first top light-emitting surface 101 of the first light-emitting chip 1 (referring to FIG. 5 and FIG. 8), and a vertical projection of the third bottom non-soldering pad area 302 of the third light-emitting chip 3 can partially fall on the first top light-emitting surface 101 of the first light-emitting chip 1 and the second top light-emitting surface 201 of the second light-emitting chip 2 (referring to FIG. 7 and FIG. 8). In addition, when the first light-emitting chip 1, the second light-emitting chip 2 and the third light-emitting chip 3 are stacked and disposed sequentially from bottom to top, a vertical projection of the second positive electrode pad 203 and a vertical projection of the second negative electrode pad 204 of the second light-emitting chip 2 do not fall on the first top light-emitting surface 101 of the first light-emitting chip 1 (referring to FIG. 5 and FIG. 8), and a vertical projection of the third positive electrode pad 303 and a vertical projection of the third negative electrode pad 304 of the third light-emitting chip 3 do not fall on the first top light-emitting surface 101 of the first light-emitting chip 1 and the second top light-emitting surface 201 of the second light-emitting chip 2 (referring to FIG. 7 and FIG. 8).

Furthermore, referring to FIG. 2 to FIG. 8, the first embodiment of the present disclosure further provides a staggered stacked light-emitting chip structure S, which includes a first light-emitting chip 1, a second light-emitting chip 2 and a third light-emitting chip 3. More particularly, the first light-emitting chip 1 has a first top light-emitting surface 101, a first bottom non-soldering pad area 102, a first positive electrode pad 103 and a first negative electrode pad 104 (referring to FIG. 2 and FIG. 3), the second light-emitting chip 2 has a second top light-emitting surface 201, a second bottom non-soldering pad area 202, a second positive electrode pad 203 and a second negative electrode pad 204 (referring to FIG. 4 and FIG. 5), and the third light-emitting chip 3 has a third top light-emitting surface 301, a third bottom non-soldering pad area 302, a third positive electrode pad 303 and a third negative electrode pad 304 (referring to FIG. 6 and FIG. 7). It should be noted that referring to FIG. 7 and FIG. 8, the first light-emitting chip 1, the second light-emitting chip 2 and the third light-emitting chip 3 can be stacked in sequence from bottom to top, and the first light-emitting chip 1, the second light-emitting chip 2 and the third light-emitting chip 3 can be horizontally staggered from each other.

For example, as shown in FIG. 7, when the first light-emitting chip 1, the second light-emitting chip 2 and the third light-emitting chip 3 are stacked and disposed sequentially from bottom to top, the first light-emitting chip 1 can be configured to be horizontally deflected (or rotated) by a first predetermined deflection angle θ1 (or a first predetermined rotation angle) relative to the second light-emitting chip 2, the second light-emitting chip 2 can be configured to be horizontally deflected (or rotated) by a second predetermined deflection angle θ2 (or a second predetermined rotation angle) relative to the third light-emitting chip 3, and the third light-emitting chip 3 can be configured to be horizontally deflected (or rotated) by a third predetermined deflection angle θ3 (or a third predetermined rotation angle) relative to the first light-emitting chip 1, and the first predetermined deflection angle θ1, the second predetermined deflection angle θ2 and the third predetermined deflection angle θ3 can be the same or different from each other. In addition, referring to FIG. 2, FIG. 4 and FIG. 6, a thickness H1 of the first light-emitting chip 1 can be less than a thickness H2 of the second light-emitting chip 2 (or the thickness H1 of the first light-emitting chip 1 may be less than the thickness of the second positive electrode pad 203 and the thickness of the second negative electrode pad 204 of the second light-emitting chip 2), the thickness H2 of the second light-emitting chip 2 can be less than a thickness H3 of the third light-emitting chip 3 (or the thickness H2 of the second light-emitting chip 2 may be less than the thickness of the third positive electrode pad 303 and the thickness of the third negative electrode pad 304 of the third light-emitting chip 3), and the thickness H1 of the first light-emitting chip 1, the thickness H2 of the second light-emitting chip 2 and the thickness H3 of the third light-emitting chip 3 can be all less than 10 μm. However, the aforementioned details are disclosed for exemplary purposes only, and are not meant to limit the scope of the present disclosure.

For example, referring to FIG. 7 and FIG. 8, when the first light-emitting chip 1, the second light-emitting chip 2 and the third light-emitting chip 3 are stacked and disposed sequentially from bottom to top, a vertical projection of the second bottom non-soldering pad area 202 of the second light-emitting chip 2 can partially fall on the first top light-emitting surface 101 of the first light-emitting chip 1, and a vertical projection of the third bottom non-soldering pad area 302 of the third light-emitting chip 3 can partially fall on the first top light-emitting surface 101 of the first light-emitting chip 1 and the second top light-emitting surface 201 of the second light-emitting chip 2. More particularly, in one of the feasible embodiments, the second light-emitting chip 2 can be directly stacked on the first top light-emitting surface 101 of the first light-emitting chip 1, and the first light-emitting chip 1 and the second light-emitting chip 2 can be insulated from each other. In addition, the third light-emitting chip 3 can be directly stacked on the second top light-emitting surface 201 of the second light-emitting chip 2, and the second light-emitting chip 2 and the third light-emitting chip 3 can be insulated from each other. However, the aforementioned details are disclosed for exemplary purposes only, and are not meant to limit the scope of the present disclosure.

For example, referring to FIG. 7 and FIG. 8, when the first light-emitting chip 1, the second light-emitting chip 2 and the third light-emitting chip 3 are stacked and disposed sequentially from bottom to top, a vertical projection of the second positive electrode pad 203 and a vertical projection of the second negative electrode pad 204 of the second light-emitting chip 2 do not fall on the first top light-emitting surface 101 of the first light-emitting chip 1, and a vertical projection of the third positive electrode pad 303 and a vertical projection of the third negative electrode pad 304 of the third light-emitting chip 3 do not fall on the first top light-emitting surface 101 of the first light-emitting chip 1 and the second top light-emitting surface 201 of the second light-emitting chip 2. That is to say, the second positive electrode pad 203 and the second negative electrode pad 204 of the second light-emitting chip 2 can be separate from the first light-emitting chip 1 and do not contact the first light-emitting chip 1, and the third positive electrode pad 303 and the third negative electrode pad 304 of the third light-emitting chip 3 can be separate from the first light-emitting chip 1 and the second light-emitting chip 2 and do not contact the first light-emitting chip 1 and the second light-emitting chip 2. However, the aforementioned details are disclosed for exemplary purposes only, and are not meant to limit the scope of the present disclosure.

For example, referring to FIG. 7 and FIG. 8, when the first light-emitting chip 1, the second light-emitting chip 2 and the third light-emitting chip 3 are stacked and disposed sequentially from bottom to top, the first top light-emitting surface 101 of the first light-emitting chip 1 has a first light-emitting area A1 (including a first left light-emitting surface and a first right light-emitting surface that are separate from each other) that is not blocked by the second bottom non-soldering pad area 202 of the second light-emitting chip 2, and the second top light-emitting surface 201 of the second light-emitting chip 2 has a second light-emitting area A2 (including a second left light-emitting surface and a second right light-emitting surface that are separate from each other) that is not blocked by the third bottom non-soldering pad area 302 of the third light-emitting chip 3, and the third top light-emitting surface 301 of the third light-emitting chip 3 has a third light-emitting area A3 (including an original complete light-emitting area) that is not blocked at all. More particularly, the first light-emitting area A1 of the first top light-emitting surface 101 can be greater than, equal to, or smaller than the second light-emitting area A2 of the second top light-emitting surface 201, and the third light-emitting area A3 of the third top light-emitting surface 301 can be larger than the first light-emitting area A1 of the first top light-emitting surface 101 and the second light-emitting area A2 of the second top light-emitting surface 201. In addition, the first light-emitting area A1 can occupy about 50% to 90% (e.g., any positive integer percentage between 50% and 90%) of a surface area of the first top light-emitting surface 101 (that is to say, approximately between 50% and 90% of the first top light-emitting surface 101 is an actual available light-emitting area that can be utilized), and the second light-emitting area A2 can occupy about 50% to 90% (e.g., any positive integer percentage between 50% and 90%) of a surface area of the second top light-emitting surface 201 (that is to say, approximately between 50% and 90% of the second top light-emitting surface 201 is an actual available light-emitting area that can be utilized). Therefore, when the first light-emitting chip 1, the second light-emitting chip 2 and the third light-emitting chip 3 are stacked in sequence, the mutual optical influence between the projection beam generated by the first light-emitting chip 1, the projection beam generated by the second light-emitting chip 2 and the projection beam generated by the third light-emitting chip 3 can be minimized (or the mutual blocking influence between the first light-emitting chip 1, the second light-emitting chip 2 and the third light-emitting chip 3 can be minimized). However, the aforementioned details are disclosed for exemplary purposes only, and are not meant to limit the scope of the present disclosure.

For example, referring to FIG. 5, FIG. 7 and FIG. 8, when the first light-emitting chip 1, the second light-emitting chip 2 and the third light-emitting chip 3 are stacked and disposed sequentially from bottom to top, the first top light-emitting surface 101 of the first light-emitting chip 1 has a first shielding area B1 that is covered or shielded by the second bottom non-soldering pad area 202 of the second light-emitting chip 2, and the second top light-emitting surface 201 of the second light-emitting chip 2 has a second shielding area B2 that is covered or shielded by the third bottom non-soldering pad area 302 of the third light-emitting chip 3. More particularly, the first shielding area B1 can occupy about 10% to 50% (e.g., any positive integer percentage between 10% and 50%) of the surface area of the first top light-emitting surface 101 (that is to say, approximately 10% to 50% of the first top light-emitting surface 101 is an unusable light-emitting area that cannot be utilized), and the second shielding area B2 can occupy about 10% to 50% (e.g., any positive integer percentage between 10% and 50%) of the surface area of the second top light-emitting surface 201 (that is to say, approximately 10% to 50% of the second top light-emitting surface 201 is an unusable light-emitting area that cannot be utilized). Therefore, when the first light-emitting chip 1, the second light-emitting chip 2 and the third light-emitting chip 3 are stacked in sequence, the mutual optical influence between the projection beam generated by the first light-emitting chip 1, the projection beam generated by the second light-emitting chip 2 and the projection beam generated by the third light-emitting chip 3 can be minimized (or the mutual blocking influence between the first light-emitting chip 1, the second light-emitting chip 2 and the third light-emitting chip 3 can be minimized). However, the aforementioned details are disclosed for exemplary purposes only, and are not meant to limit the scope of the present disclosure.

For example, referring to FIG. 2, FIG. 4 and FIG. 6, in one of the feasible embodiments, the first light-emitting chip 1 can be configured as a red LED die (i.e., a red light die that has not yet been packaged) for providing a red light beam, and the second light-emitting chip 2 can be configured as a green LED die (i.e., a green light die that has not yet been packaged) for providing a green light beam, and the third light-emitting chip 3 can be configured as a blue LED die (i.e., a blue light die that has not yet been packaged) for providing a blue light beam. More particularly, referring to FIG. 7 and FIG. 8, when the first light-emitting chip 1, the second light-emitting chip 2 and the third light-emitting chip 3 are stacked and disposed sequentially from bottom to top, the green light beam provided by the green LED die (such as the second light-emitting chip 2) can be projected upward without passing through the red LED die (such as the first light-emitting chip 1), and the blue light beam provided by the blue LED die (such as the third light-emitting chip 3) can be projected upward without passing through the red LED die (such as the first light-emitting chip 1) and the green LED die (such as the second light-emitting chip 2). Therefore, when the red light beam provided by the red LED die, the green light beam provided by the green LED die and the blue light beam provided by the blue LED die cooperate (or mix) with each other, the staggered stacked light-emitting chip structure S can be allowed to be configured as one of the image pixels of an image display device D. However, the aforementioned details are disclosed for exemplary purposes only, and are not meant to limit the scope of the present disclosure.

### Second Embodiment

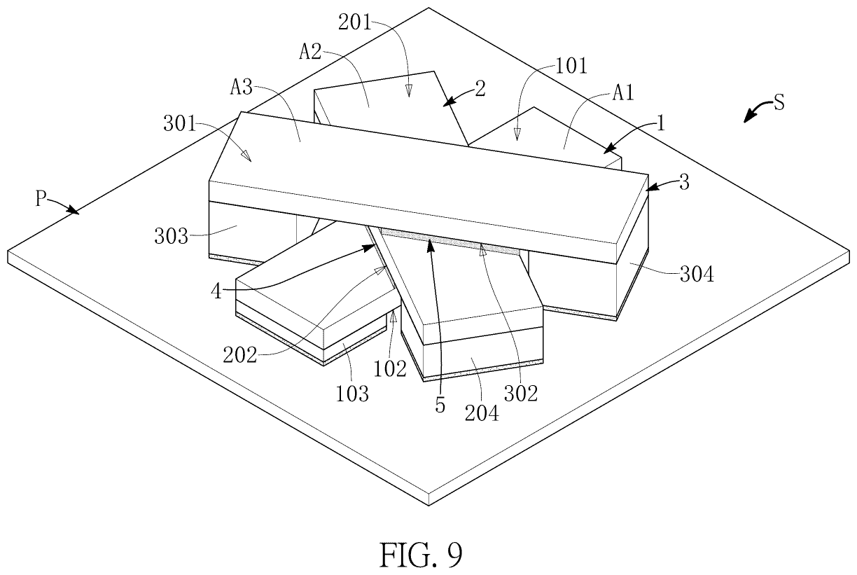

Referring to FIG. 9, a second embodiment of the present disclosure provides a staggered stacked light-emitting chip structure S, which includes a first light-emitting chip 1, a second light-emitting chip 2 and a third light-emitting chip 3. Comparing FIG. 9 with FIG. 8, the main difference between the second embodiment and the first embodiment is as follows: in the second embodiment, the second light-emitting chip 2 can be disposed on the first top light-emitting surface 101 of the first light-emitting chip 1 through a first light-transmitting insulating layer 4 in order to insulate the first light-emitting chip 1 and the second light-emitting chip 2 from each other, and the third light-emitting chip 3 can be disposed on the second top light-emitting surface 201 of the second light-emitting chip 2 through a second light-transmitting insulating layer 5 in order to insulate the second light-emitting chip 2 and the third light-emitting chip 3 from each other.

For example, any one of the first light-emitting chip 1, the second light-emitting chip 2 and the third light-emitting chip 3 at least includes a gallium nitride (GaN) material layer, a quantum well (MQW) structural layer, an N-type gallium nitride material layer, a P-type gallium nitride material layer, a positive electrode layer and a negative electrode layer that can cooperate with each other. Therefore, the first top light-emitting surface 101 of the first light-emitting chip 1, the second top light-emitting surface 201 of the second light-emitting chip 2, and the third top light-emitting surface 301 of the third light-emitting chip 3 are all gallium nitride material surfaces, and the first bottom non-soldering pad area 102 of the first light-emitting chip 1, the second bottom non-soldering pad area 202 of the second light-emitting chip 2, and the third bottom non-soldering pad area 302 of the third light-emitting chip 3 are all P-type gallium nitride material surfaces or N-type gallium nitride material surfaces. That is to say, when the second light-emitting chip 2 is disposed on the first top light-emitting surface 101 of the first light-emitting chip 1, the first light-emitting chip 1 (or the first top light-emitting surface 101) and the second light-emitting chip 2 (or the second bottom non-soldering pad area 202) can be insulated from each other through the use of a first light-transmitting insulating layer 4 (such as silicone, epoxy resin or any light-transmitting insulating material). In addition, when the third light-emitting chip 3 is disposed on the second top light-emitting surface 201 of the second light-emitting chip 2, the second light-emitting chip 2 (or the second top light-emitting surface 201) and the third light-emitting chip 3 (or the third bottom non-soldering pad area 302) can be insulated from each other through the use of a second light-transmitting insulating layer 5 (such as silicone, epoxy resin or any light-transmitting insulating material). However, the aforementioned details are disclosed for exemplary purposes only, and are not meant to limit the scope of the present disclosure.

### Third Embodiment

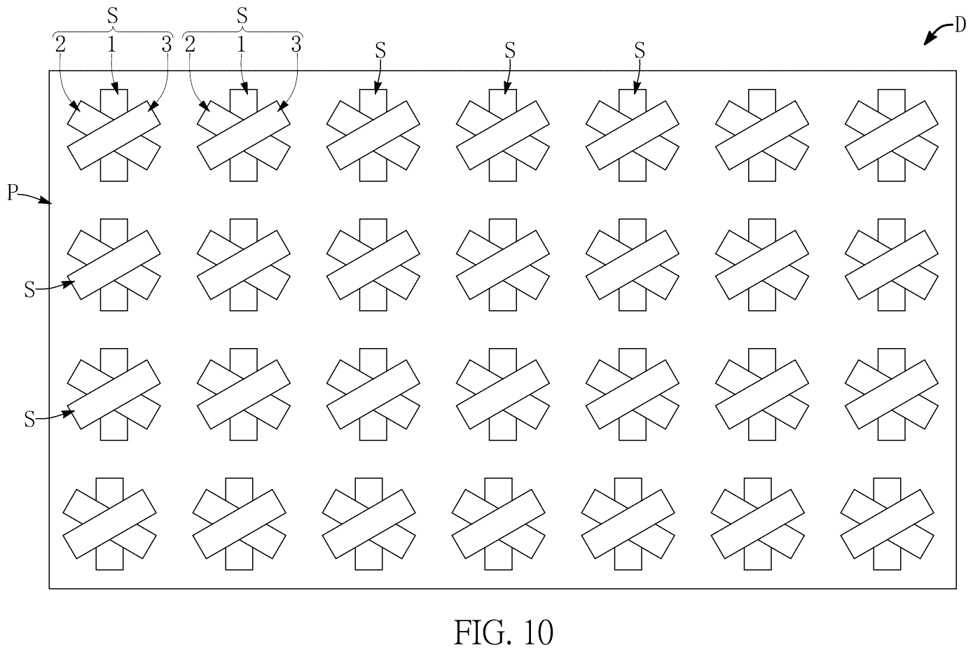

Referring to FIG. 10, a third embodiment of the present disclosure provides an image display device D, which includes a circuit substrate P and a plurality of staggered stacked light-emitting chip structures S, and the staggered stacked light-emitting chip structures S are disposed on the circuit substrate P and electrically connected to the circuit substrate P. More particularly, each staggered stacked light-emitting chip structure S used in the third embodiment can choose to adopt the staggered stacked light-emitting chip structure S provided in the first embodiment or the second embodiment.

For example, referring to FIG. 2, FIG. 4 and FIG. 6, each of the staggered stacked light-emitting chip structures S includes a first light-emitting chip 1, a second light-emitting chip 2 and a third light-emitting chip 3, in which the first light-emitting chip 1 has a first top light-emitting surface 101, a first bottom non-soldering pad area 102, a first positive electrode pad 103 and a first negative electrode pad 104, the second light-emitting chip 2 has a second top light-emitting surface 201, a second bottom non-soldering pad area 202, a second positive electrode pad 203 and a second negative electrode pad 204, and the third light-emitting chip 3 has a third top light-emitting surface 301, a third bottom non-soldering pad area 302, a third positive electrode pad 303 and a third negative electrode pad 304. Therefore, when the first light-emitting chip 1, the second light-emitting chip 2 and the third light-emitting chip 3 are stacked sequentially from bottom to top, the first light-emitting chip 1, the second light-emitting chip 2 and the third light-emitting chip 3 can be staggered from each other or rotated correspondingly by a predetermined rotation angle in the horizontal direction.

### Beneficial Effects of the Embodiments

In conclusion, in the staggered stacked light-emitting chip structure S provided by the present disclosure, by virtue of “the first light-emitting chip 1, the second light-emitting chip 2 and the third light-emitting chip 3 being stacked sequentially from bottom to top,” “the first light-emitting chip 1, the second light-emitting chip 2 and the third light-emitting chip 3 being horizontally staggered from each other,” “the vertical projection of the second positive electrode pad 203 and the vertical projection of the second negative electrode pad 204 of the second light-emitting chip 2 that do not fall on the first top light-emitting surface 101 of the first light-emitting chip 1” and “the vertical projection of the third positive electrode pad 303 and the vertical projection of the third negative electrode pad 304 of the third light-emitting chip 3 that do not fall on the first top light-emitting surface 101 of the first light-emitting chip 1 and the second top light-emitting surface 201 of the second light-emitting chip 2,” when the first light-emitting chip 1, the second light-emitting chip 2 and the third light-emitting chip 3 are stacked in sequence, the mutual optical influence between the projection beam generated by the first light-emitting chip 1, the projection beam generated by the second light-emitting chip 2 and the projection beam generated by the third light-emitting chip 3 can be minimized (or the mutual blocking influence between the first light-emitting chip 1, the second light-emitting chip 2 and the third light-emitting chip 3 can be minimized).

Furthermore, in the method for manufacturing the staggered stacked light-emitting chip structure S provided by the present disclosure, by virtue of “providing a circuit substrate P, placing a first light-emitting chip 1 on the circuit substrate P to electrically connect to the circuit substrate P, stacking a second light-emitting chip 2 on the first light-emitting chip 1 to electrically connect to the circuit substrate P, and stacking a third light-emitting chip 3 on the second light-emitting chip 2 to electrically connect to the circuit substrate P,” “the first light-emitting chip 1, the second light-emitting chip 2 and the third light-emitting chip 3 being stacked sequentially from bottom to top,” “the first light-emitting chip 1, the second light-emitting chip 2 and the third light-emitting chip 3 being horizontally staggered from each other,” “the vertical projection of the second positive electrode pad 203 and the vertical projection of the second negative electrode pad 204 of the second light-emitting chip 2 that do not fall on the first top light-emitting surface 101 of the first light-emitting chip 1” and “the vertical projection of the third positive electrode pad 303 and the vertical projection of the third negative electrode pad 304 of the third light-emitting chip 3 that do not fall on the first top light-emitting surface 101 of the first light-emitting chip 1 and the second top light-emitting surface 201 of the second light-emitting chip 2,” when the first light-emitting chip 1, the second light-emitting chip 2 and the third light-emitting chip 3 are stacked in sequence, the mutual optical influence between the projection beam generated by the first light-emitting chip 1, the projection beam generated by the second light-emitting chip 2 and the projection beam generated by the third light-emitting chip 3 can be minimized (or the mutual blocking influence between the first light-emitting chip 1, the second light-emitting chip 2 and the third light-emitting chip 3 can be minimized).

Moreover, in the image display device D provided by the present disclosure, by virtue of “the staggered stacked light-emitting chip structures S being disposed on the circuit substrate P and electrically connected to the circuit substrate P,” “each of the staggered stacked light-emitting chip structures S including a first light-emitting chip 1, a second light-emitting chip 2 and a third light-emitting chip 3,” “the first light-emitting chip 1, the second light-emitting chip 2 and the third light-emitting chip 3 being stacked sequentially from bottom to top,” “the first light-emitting chip 1, the second light-emitting chip 2 and the third light-emitting chip 3 being horizontally staggered from each other,” “the vertical projection of the second positive electrode pad 203 and the vertical projection of the second negative electrode pad 204 of the second light-emitting chip 2 that do not fall on the first top light-emitting surface 101 of the first light-emitting chip 1” and “the vertical projection of the third positive electrode pad 303 and the vertical projection of the third negative electrode pad 304 of the third light-emitting chip 3 that do not fall on the first top light-emitting surface 101 of the first light-emitting chip 1 and the second top light-emitting surface 201 of the second light-emitting chip 2,” when the first light-emitting chip 1, the second light-emitting chip 2 and the third light-emitting chip 3 are stacked in sequence, the mutual optical influence between the projection beam generated by the first light-emitting chip 1, the projection beam generated by the second light-emitting chip 2 and the projection beam generated by the third light-emitting chip 3 can be minimized (or the mutual blocking influence between the first light-emitting chip 1, the second light-emitting chip 2 and the third light-emitting chip 3 can be minimized).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A staggered stacked light-emitting chip structure, comprising:
a first light-emitting chip having a first top light-emitting surface, a first bottom non-soldering pad area, a first positive electrode pad and a first negative electrode pad;
a second light-emitting chip having a second top light-emitting surface, a second bottom non-soldering pad area, a second positive electrode pad and a second negative electrode pad; and
a third light-emitting chip having a third top light-emitting surface, a third bottom non-soldering pad area, a third positive electrode pad and a third negative electrode pad;
wherein the first light-emitting chip, the second light-emitting chip and the third light-emitting chip are stacked sequentially from bottom to top, and the first light-emitting chip, the second light-emitting chip and the third light-emitting chip are horizontally staggered from each other;
wherein a vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip;
wherein a vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

2. The staggered stacked light-emitting chip structure according to claim 1,
wherein the second light-emitting chip is disposed on the first top light-emitting surface of the first light-emitting chip through a first light-transmitting insulating layer, so that the first light-emitting chip and the second light-emitting chip are insulated from each other;
wherein the third light-emitting chip is disposed on the second top light-emitting surface of the second light-emitting chip through a second light-transmitting insulating layer, so that the second light-emitting chip and the third light-emitting chip are insulated from each other;
wherein the first top light-emitting surface of the first light-emitting chip, the second top light-emitting surface of the second light-emitting chip, and the third top light-emitting surface of the third light-emitting chip are all gallium nitride material surfaces, and the first bottom non-soldering pad area of the first light-emitting chip, the second bottom non-soldering pad area of the second light-emitting chip, and the third bottom non-soldering pad area of the third light-emitting chip are all P-type gallium nitride material surfaces or N-type gallium nitride material surfaces;
wherein the first light-emitting chip is configured to be horizontally deflected by a first predetermined deflection angle relative to the second light-emitting chip, the second light-emitting chip is configured to be horizontally deflected by a second predetermined deflection angle relative to the third light-emitting chip, and the third light-emitting chip is configured to be horizontally deflected by a third predetermined deflection angle relative to the first light-emitting chip, and the first predetermined deflection angle, the second predetermined deflection angle and the third predetermined deflection angle are the same or different from each other.

3. The staggered stacked light-emitting chip structure according to claim 1,
wherein the second light-emitting chip is directly stacked on the first top light-emitting surface of the first light-emitting chip, and the first light-emitting chip and the second light-emitting chip are insulated from each other;
wherein the third light-emitting chip is directly stacked on the second top light-emitting surface of the second light-emitting chip, and the second light-emitting chip and the third light-emitting chip are insulated from each other;
wherein the first top light-emitting surface of the first light-emitting chip has a first light-emitting area that is not blocked by the second bottom non-soldering pad area of the second light-emitting chip, and the second top light-emitting surface of the second light-emitting chip has a second light-emitting area that is not blocked by the third bottom non-soldering pad area of the third light-emitting chip, and the third top light-emitting surface of the third light-emitting chip has a third light-emitting area that is not blocked at all;
wherein the first light-emitting area of the first top light-emitting surface is greater than, equal to, or smaller than the second light-emitting area of the second top light-emitting surface, and the third light-emitting area of the third top light-emitting surface is larger than the first light-emitting area of the first top light-emitting surface and the second light-emitting area of the second top light-emitting surface;
wherein the first light-emitting area occupies 50% to 90% of a surface area of the first top light-emitting surface, and the second light-emitting area occupies 50% to 90% of a surface area of the second top light-emitting surface;
wherein the first top light-emitting surface of the first light-emitting chip has a first shielding area that is covered by the second bottom non-soldering pad area of the second light-emitting chip, and the second top light-emitting surface of the second light-emitting chip has a second shielding area that is covered by the third bottom non-soldering pad area of the third light-emitting chip;
wherein the first shielding area occupies 10% to 50% of the surface area of the first top light-emitting surface, and the second shielding area occupies 10% to 50% of the surface area of the second top light-emitting surface.

4. The staggered stacked light-emitting chip structure according to claim 1,
wherein the second positive electrode pad and the second negative electrode pad of the second light-emitting chip are separate from the first light-emitting chip and do not contact the first light-emitting chip, and the third positive electrode pad and the third negative electrode pad of the third light-emitting chip is separate from the first light-emitting chip and the second light-emitting chip and do not contact the first light-emitting chip and the second light-emitting chip;
wherein a thickness of the first light-emitting chip is less than a thickness of the second light-emitting chip, the thickness of the second light-emitting chip is less than a thickness of the third light-emitting chip, and the thickness of the first light-emitting chip, the thickness of the second light-emitting chip and the thickness of the third light-emitting chip are all less than 10 μm;
wherein the first light-emitting chip is configured as a red LED die for providing a red light beam, and the second light-emitting chip is configured as a green LED die for providing a green light beam, and the third light-emitting chip is configured as a blue LED die for providing a blue light beam;
wherein the green light beam provided by the green LED die is projected upward without passing through the red LED die, and the blue light beam provided by the blue LED die is projected upward without passing through the red LED die and the green LED die;
wherein, when the red light beam provided by the red LED die, the green light beam provided by the green LED die and the blue light beam provided by the blue LED die cooperate with each other, the staggered stacked light-emitting chip structure is allowed to be configured as an image pixel of an image display device.

5. A method for manufacturing a staggered stacked light-emitting chip structure, comprising:
providing a circuit substrate;
placing a first light-emitting chip on the circuit substrate to electrically connect to the circuit substrate, wherein the first light-emitting chip has a first top light-emitting surface, a first bottom non-soldering pad area, a first positive electrode pad and a first negative electrode pad;
stacking a second light-emitting chip on the first light-emitting chip to electrically connect to the circuit substrate, wherein the second light-emitting chip has a second top light-emitting surface, a second bottom non-soldering pad area, a second positive electrode pad and a second negative electrode pad; and
stacking a third light-emitting chip on the second light-emitting chip to electrically connect to the circuit substrate, wherein the third light-emitting chip has a third top light-emitting surface, a third bottom non-soldering pad area, a third positive electrode pad and a third negative electrode pad;
wherein the first light-emitting chip, the second light-emitting chip and the third light-emitting chip are stacked sequentially from bottom to top, and the first light-emitting chip, the second light-emitting chip and the third light-emitting chip are horizontally staggered from each other;
wherein a vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip;
wherein a vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

6. The method according to claim 5,
wherein the second light-emitting chip is disposed on the first top light-emitting surface of the first light-emitting chip through a first light-transmitting insulating layer, so that the first light-emitting chip and the second light-emitting chip are insulated from each other;
wherein the third light-emitting chip is disposed on the second top light-emitting surface of the second light-emitting chip through a second light-transmitting insulating layer, so that the second light-emitting chip and the third light-emitting chip are insulated from each other;
wherein the first top light-emitting surface of the first light-emitting chip, the second top light-emitting surface of the second light-emitting chip, and the third top light-emitting surface of the third light-emitting chip are all gallium nitride material surfaces, and the first bottom non-soldering pad area of the first light-emitting chip, the second bottom non-soldering pad area of the second light-emitting chip, and the third bottom non-soldering pad area of the third light-emitting chip are all P-type gallium nitride material surfaces or N-type gallium nitride material surfaces;
wherein the first light-emitting chip is configured to be horizontally deflected by a first predetermined deflection angle relative to the second light-emitting chip, the second light-emitting chip is configured to be horizontally deflected by a second predetermined deflection angle relative to the third light-emitting chip, and the third light-emitting chip is configured to be horizontally deflected by a third predetermined deflection angle relative to the first light-emitting chip, and the first predetermined deflection angle, the second predetermined deflection angle and the third predetermined deflection angle are the same or different from each other.

7. The method according to claim 5,
wherein the second light-emitting chip is directly stacked on the first top light-emitting surface of the first light-emitting chip, and the first light-emitting chip and the second light-emitting chip are insulated from each other;
wherein the third light-emitting chip is directly stacked on the second top light-emitting surface of the second light-emitting chip, and the second light-emitting chip and the third light-emitting chip are insulated from each other;
wherein the first top light-emitting surface of the first light-emitting chip has a first light-emitting area that is not blocked by the second bottom non-soldering pad area of the second light-emitting chip, and the second top light-emitting surface of the second light-emitting chip has a second light-emitting area that is not blocked by the third bottom non-soldering pad area of the third light-emitting chip, and the third top light-emitting surface of the third light-emitting chip has a third light-emitting area that is not blocked at all;
wherein the first light-emitting area of the first top light-emitting surface is greater than, equal to, or smaller than the second light-emitting area of the second top light-emitting surface, and the third light-emitting area of the third top light-emitting surface is larger than the first light-emitting area of the first top light-emitting surface and the second light-emitting area of the second top light-emitting surface;
wherein the first light-emitting area occupies 50% to 90% of a surface area of the first top light-emitting surface, and the second light-emitting area occupies 50% to 90% of a surface area of the second top light-emitting surface;
wherein the first top light-emitting surface of the first light-emitting chip has a first shielding area that is covered by the second bottom non-soldering pad area of the second light-emitting chip, and the second top light-emitting surface of the second light-emitting chip has a second shielding area that is covered by the third bottom non-soldering pad area of the third light-emitting chip;
wherein the first shielding area occupies 10% to 50% of the surface area of the first top light-emitting surface, and the second shielding area occupies 10% to 50% of the surface area of the second top light-emitting surface.

8. The method according to claim 5,
wherein the second positive electrode pad and the second negative electrode pad of the second light-emitting chip are separate from the first light-emitting chip and do not contact the first light-emitting chip, and the third positive electrode pad and the third negative electrode pad of the third light-emitting chip is separate from the first light-emitting chip and the second light-emitting chip and do not contact the first light-emitting chip and the second light-emitting chip;
wherein a thickness of the first light-emitting chip is less than a thickness of the second light-emitting chip, the thickness of the second light-emitting chip is less than a thickness of the third light-emitting chip, and the thickness of the first light-emitting chip, the thickness of the second light-emitting chip and the thickness of the third light-emitting chip are all less than 10 μm;
wherein the first light-emitting chip is configured as a red LED die for providing a red light beam, and the second light-emitting chip is configured as a green LED die for providing a green light beam, and the third light-emitting chip is configured as a blue LED die for providing a blue light beam;
wherein the green light beam provided by the green LED die is projected upward without passing through the red LED die, and the blue light beam provided by the blue LED die is projected upward without passing through the red LED die and the green LED die;
wherein, when the red light beam provided by the red LED die, the green light beam provided by the green LED die and the blue light beam provided by the blue LED die cooperate with each other, the staggered stacked light-emitting chip structure is allowed to be configured as an image pixel of an image display device.

9. An image display device, comprising:
a circuit substrate; and
a plurality of staggered stacked light-emitting chip structures disposed on the circuit substrate and electrically connected to the circuit substrate;
wherein each of the staggered stacked light-emitting chip structures includes a first light-emitting chip, a second light-emitting chip and a third light-emitting chip;
wherein the first light-emitting chip has a first top light-emitting surface, a first bottom non-soldering pad area, a first positive electrode pad and a first negative electrode pad, the second light-emitting chip has a second top light-emitting surface, a second bottom non-soldering pad area, a second positive electrode pad and a second negative electrode pad, and the third light-emitting chip has a third top light-emitting surface, a third bottom non-soldering pad area, a third positive electrode pad and a third negative electrode pad;
wherein the first light-emitting chip, the second light-emitting chip and the third light-emitting chip are stacked sequentially from bottom to top, and the first light-emitting chip, the second light-emitting chip and the third light-emitting chip are horizontally staggered from each other;
wherein a vertical projection of the second bottom non-soldering pad area of the second light-emitting chip partially falls on the first top light-emitting surface of the first light-emitting chip, and a vertical projection of the third bottom non-soldering pad area of the third light-emitting chip partially falls on the first top light-emitting surface of the first light-emitting chip and the second top light-emitting surface of the second light-emitting chip;
wherein a vertical projection of the second positive electrode pad and a vertical projection of the second negative electrode pad of the second light-emitting chip do not fall on the first top light-emitting surface of the first light-emitting chip, and a vertical projection of the third positive electrode pad and a vertical projection of the third negative electrode pad of the third light-emitting chip do not fall on the first top light-emitting surface of the first light-emitting chip and the second top light-emitting surface of the second light-emitting chip.

10. The image display device according to claim 9,
wherein the second light-emitting chip is disposed on the first top light-emitting surface of the first light-emitting chip through a first light-transmitting insulating layer, so that the first light-emitting chip and the second light-emitting chip are insulated from each other;
wherein the third light-emitting chip is disposed on the second top light-emitting surface of the second light-emitting chip through a second light-transmitting insulating layer, so that the second light-emitting chip and the third light-emitting chip are insulated from each other;
wherein the first top light-emitting surface of the first light-emitting chip, the second top light-emitting surface of the second light-emitting chip, and the third top light-emitting surface of the third light-emitting chip are all gallium nitride material surfaces, and the first bottom non-soldering pad area of the first light-emitting chip, the second bottom non-soldering pad area of the second light-emitting chip, and the third bottom non-soldering pad area of the third light-emitting chip are all P-type gallium nitride material surfaces or N-type gallium nitride material surfaces;
wherein the first light-emitting chip is configured to be horizontally deflected by a first predetermined deflection angle relative to the second light-emitting chip, the second light-emitting chip is configured to be horizontally deflected by a second predetermined deflection angle relative to the third light-emitting chip, and the third light-emitting chip is configured to be horizontally deflected by a third predetermined deflection angle relative to the first light-emitting chip, and the first predetermined deflection angle, the second predetermined deflection angle and the third predetermined deflection angle are the same or different from each other;
wherein the first top light-emitting surface of the first light-emitting chip has a first light-emitting area that is not blocked by the second bottom non-soldering pad area of the second light-emitting chip, and the second top light-emitting surface of the second light-emitting chip has a second light-emitting area that is not blocked by the third bottom non-soldering pad area of the third light-emitting chip, and the third top light-emitting surface of the third light-emitting chip has a third light-emitting area that is not blocked at all;
wherein the first light-emitting area of the first top light-emitting surface is greater than, equal to, or smaller than the second light-emitting area of the second top light-emitting surface, and the third light-emitting area of the third top light-emitting surface is larger than the first light-emitting area of the first top light-emitting surface and the second light-emitting area of the second top light-emitting surface;
wherein the first light-emitting area occupies 50% to 90% of a surface area of the first top light-emitting surface, and the second light-emitting area occupies 50% to 90% of a surface area of the second top light-emitting surface;
wherein the first top light-emitting surface of the first light-emitting chip has a first shielding area that is covered by the second bottom non-soldering pad area of the second light-emitting chip, and the second top light-emitting surface of the second light-emitting chip has a second shielding area that is covered by the third bottom non-soldering pad area of the third light-emitting chip;
wherein the first shielding area occupies 10% to 50% of the surface area of the first top light-emitting surface, and the second shielding area occupies 10% to 50% of the surface area of the second top light-emitting surface;
wherein the second positive electrode pad and the second negative electrode pad of the second light-emitting chip are separate from the first light-emitting chip and do not contact the first light-emitting chip, and the third positive electrode pad and the third negative electrode pad of the third light-emitting chip is separate from the first light-emitting chip and the second light-emitting chip and do not contact the first light-emitting chip and the second light-emitting chip;
wherein a thickness of the first light-emitting chip is less than a thickness of the second light-emitting chip, the thickness of the second light-emitting chip is less than a thickness of the third light-emitting chip, and the thickness of the first light-emitting chip, the thickness of the second light-emitting chip and the thickness of the third light-emitting chip are all less than 10 μm;
wherein the first light-emitting chip is configured as a red LED die for providing a red light beam, and the second light-emitting chip is configured as a green LED die for providing a green light beam, and the third light-emitting chip is configured as a blue LED die for providing a blue light beam;
wherein the green light beam provided by the green LED die is projected upward without passing through the red LED die, and the blue light beam provided by the blue LED die is projected upward without passing through the red LED die and the green LED die;
wherein, when the red light beam provided by the red LED die, the green light beam provided by the green LED die and the blue light beam provided by the blue LED die cooperate with each other, the staggered stacked light-emitting chip structure is allowed to be configured as an image pixel of an image display device.
